(19) United States
(12) Patent Application Publication
(10) Pub. No.: US 2023/0361097 A1
(43) Pub. Date: Nov. 9, 2023

(54) DISPLAY DEVICE, ELECTRONIC DEVICE, AND METHOD OF MANUFACTURING DISPLAY DEVICE

(71) Applicants: SONY GROUP CORPORATION, TOKYO (JP); SONY SEMICONDUCTOR SOLUTIONS CORPORATION, KANAGAWA (JP)

(72) Inventors: YUSUKE OYAMA, TOKYO (JP); SHUTARO KUROKAWA, TOKYO (JP); AKIRA OHMAE, KANAGAWA (JP)

(21) Appl. No.: 18/246,156

(22) PCT Filed: Oct. 11, 2021
(86) PCT No.: PCT/JP2021/037577

§ 371 Date: Mar. 21, 2023

(30) Foreign Application Priority Data
Oct. 15, 2020 (JP) 2020-174205

(51) Int. Cl. H01L 25/16; H01L 33/58

(52) U.S. Cl. CPC H01L 25/167; H01L 33/58; H01L 33/22

(57) ABSTRACT

A display device, a method of manufacturing a display device, and an electronic device excellent in light extraction efficiency and viewing angle characteristic are provided. A display device includes: a substrate; a light emitting element attached to the substrate; and a sealing layer that seals the light emitting element, in which an uneven portion having a plurality of concave portions and a plurality of convex portions is provided on a light emitting surface of the light emitting element, and a low refractive index portion having a refractive index lower than that of the sealing layer is formed at a periphery of an immediately above portion above the light emitting element in the sealing layer.

### TECHNICAL FIELD

The present disclosure relates to a display device, an electronic device, and a method of manufacturing a display device. The present disclosure particularly relates to a display device including a light emitting element, an electronic device including a display device including a light emitting element, and a method of manufacturing a display device including a light emitting element.

### BACKGROUND ART

A display device including a light emitting element is demanded to efficiently extract light to the outside of a layer sealing the light emitting element, that is, to improve so-called light extraction efficiency. For example, Patent Document 1 discloses a technique of providing a light guide portion formed in a tubular shape immediately above a light emitting element.

### CITATION LIST

### Patent Document

Patent Document 1: Japanese Patent Application Laid-Open No. 2010-271456

### SUMMARY OF THE INVENTION

### Problems to be Solved by the Invention

In the technique of Patent Document 1, there is room for improvement in terms of both improvement of light extraction efficiency and a viewing angle characteristic.

The present disclosure has been made in view of the above-described points, and an object of the present disclosure is to provide a display device, a method of manufacturing a display device, and an electronic device excellent in light extraction efficiency and a viewing angle characteristic.

### Solutions to Problems

The present disclosure is, for example, (1) a display device including:

a substrate;

a light emitting element attached to the substrate; and

a sealing layer that seals the light emitting element,

in which a plurality of uneven portions formed periodically is provided on a light emitting surface of the light emitting element, and

in the sealing layer, a first refractive index portion that forms an immediately above portion of the light emitting element and a second low refractive index portion that is positioned at the periphery of the immediately above portion and that has a refractive index lower than that of the first refractive index portion are formed.

Furthermore, the present disclosure may be, for example, (2) an electronic device including the display device according to above-described (1).

The present disclosure may be (3) a method of manufacturing a display device, including:

forming a first layer in which a light emitting element is embedded by applying a first material to form a sealing layer that seals the light emitting element onto a substrate on which the light emitting element provided with an uneven portion on a light emitting surface is mounted at a predetermined position;

forming a low refractive index portion having a refractive index smaller than that of the first layer by applying a second material different from the first material onto the first layer;

exposing the first layer from an opening by forming the opening in a predetermined portion of the low refractive index portion, the predetermined portion including at least a portion immediately above the light emitting element; and

forming the second layer by applying the first material to cover the first layer exposed in the opening and the low refractive index portion, the second layer and the first layer serving as the sealing layer.

The present disclosure may be (4) a method of manufacturing a display device, including:

forming a first layer in which a light emitting element is embedded by applying a first material to form a sealing layer that seals the light emitting element onto a substrate on which the light emitting element provided with an uneven portion on a light emitting surface is mounted at a predetermined position;

layering a low refractive index film on the first layer, the low refractive index film having a refractive index smaller than that of the first layer, the low refractive index film having an opening formed in a portion corresponding to a predetermined portion including at least a portion immediately above the light emitting element; and

forming the second layer by applying the first material to cover the first layer exposed in the opening and the low refractive index film, the first layer and the second layer serving as the sealing layer.

### BRIEF DESCRIPTION OF DRAWINGS

FIG. 1 is a cross-sectional view for describing an embodiment of a display device.

FIG. 2 is a plan view for describing one embodiment of the display device.

FIG. 3A is a plan view for describing an embodiment of a light emitting element provided in the display device. FIG. 3B is a partial enlarged view of a region S1 surrounded by an alternate long and short dash line in FIG. 1.

FIG. 4A is a cross-sectional view for describing an example of dimensions of the display device. FIG. 4B is a plan view for describing an embodiment of dimensions of the display device.

FIGS. 5A and 5B are cross-sectional views for describing another embodiment of the display device.

FIGS. 6A and 6B are cross-sectional views for describing another embodiment of the display device.

FIGS. 7A, 7B, and 7C are cross-sectional views for describing another embodiment of the light emitting element.

FIG. 8 is a perspective view for describing another embodiment of the light emitting element.

FIGS. 9A, 9B, 9C, 9D, and 9E are cross-sectional views for describing an embodiment of a method of manufacturing a display device.

FIGS. 10A, 10B, and 10C are cross-sectional views for describing an embodiment of the method of manufacturing a display device.

FIG. 11 is a diagram illustrating results of wave simulation.

FIG. 12 is a diagram illustrating simulation results regarding light extraction efficiency.

FIGS. 13A and 13B are diagrams for describing an embodiment of an electronic device using a display device.

FIG. 14 is a view for describing an embodiment of an electronic device using a display device.

FIG. 15 is a view for describing an embodiment of an electronic device using a display device.

FIG. 16 is a cross-sectional view for describing an embodiment of an illumination device.

### MODE FOR CARRYING OUT THE INVENTION

Hereinafter, an embodiment according to the present disclosure and the like will be described with reference to the accompanying drawings. Note that the description will be given in the following order. In the present specification and the drawings, components having substantially the same functional configuration are denoted by the same reference signs and the same description is not repeated.

Note that the description will be given in the following order.
1. Display device
2. Manufacturing method
3. Operation and effect
4. Simulation example
5. Application examples
6. Illumination device

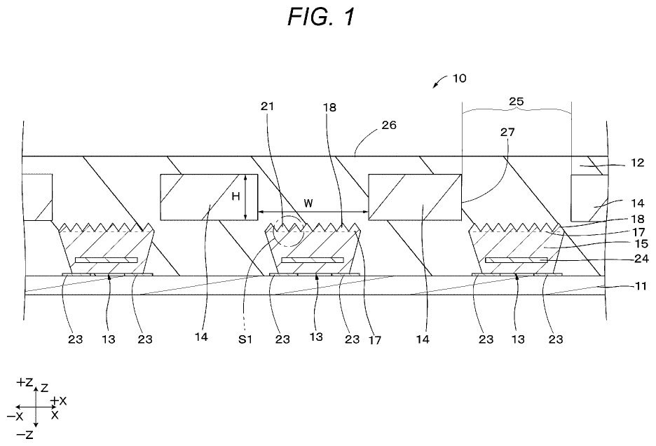

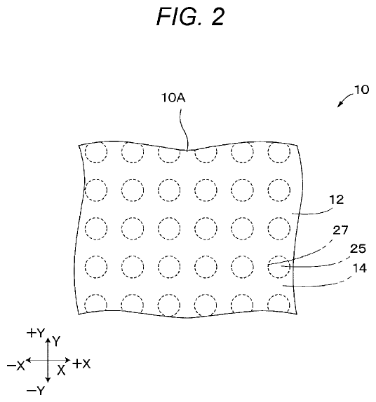

The following description is for preferred specific examples of the present disclosure, and the content of the present disclosure is not limited to these embodiments and the like. Furthermore, in the following description, directions such as front and back, left and right, and up and down are indicated in consideration of convenience of description, but the content of the present disclosure is not limited to these directions. In an example of FIGS. 1 and 2, it is assumed that the Z-axis direction is the vertical direction (the upper side is +Z direction and the lower side is −Z direction), the X-axis direction is the front-back direction (the front side is +X direction and the back side is −X direction), and the Y-axis direction is the left-right direction (the right side is +Y direction and the left side is the −Y direction), and the description will be made on the basis of this assumption. The same applies to FIGS. 3 to 10 and 16. The relative magnitude ratios of the sizes and thicknesses of the layers illustrated in the drawings such as FIG. 1 are described for convenience, and do not limit actual magnitude ratios. The above-described definition of the directions and the magnitude ratios also apply to each of the drawings of FIGS. 2 to 10 and 16.

### 1 First Embodiment

### [1-1 Configuration of Display Device]

FIG. 1 is a cross-sectional view illustrating a configuration example of a display device 10 according to an embodiment of the present disclosure. The display device 10 includes a substrate 11, a plurality of light emitting elements 13, uneven portions 18, a sealing layer 12, and a low refractive index portion 14.

In the display device 10, the substrate 11 is located on the rear surface side of the display device 10, and a direction (+Z direction) from the substrate 11 toward the light emitting elements 13 is a front surface side (display surface 10A side) direction of the display device 10. In the following description, in each layer included in the display device 10, a surface on the display surface 10A side of the display device 10 is referred to as a first surface (upper surface), and a surface on the rear surface side of the display device 10 is referred to as a second surface (lower surface).

The display device 10 may be a microdisplay. The display device 10 may be used for various electronic devices. Examples of the electronic device in which the display device 10 is used include a display device for virtual reality (VR), mixed reality (MR), or augmented reality (AR), an electronic view finder (EVF), a small projector, and the like.

(Substrate)

The substrate 11 is provided with various circuits for driving the plurality of light emitting elements 13. That is, the substrate 11 is provided with a drive circuit including a sampling transistor and a driving transistor that control driving the plurality of light emitting elements 13, and a power supply circuit that supplies power to the plurality of light emitting elements 13 (both not illustrated).

The substrate 11 may be formed from, for example, a glass or a resin having low permeability for moisture and oxygen, or may be formed from a semiconductor, from which a transistor or the like is easily formed. Specifically, the substrate 11 may be a glass substrate, a semiconductor substrate, a resin substrate, or the like. The glass substrate includes, for example, high strain point glass, soda glass, borosilicate glass, forsterite, lead glass, quartz glass, or the like. The semiconductor substrate includes, for example, amorphous silicon, polycrystalline silicon, single crystal silicon, or the like. The resin substrate includes, for example, at least one selected from the group consisting of polymethyl methacrylate, polyvinyl alcohol, polyvinyl phenol, polyether sulfone, polyimide, polycarbonate, polyethylene terephthalate, polyethylene naphthalate, or the like.

A plurality of contact plugs 23 for connecting the light emitting elements 13 and the drive circuit are provided on the first surface of the substrate 11.

(Light Emitting Element)

The plurality of light emitting elements 13 is provided on the first surface side of the substrate 11. The plurality of light emitting elements 13 is two-dimensionally arranged in a prescribed arrangement pattern, for example, a matrix, or the like. Examples of the light emitting elements 13 include, for example, an LED, a micro-LED, an organic light emitting diode (OLED), and a micro-OLED (MOLED). The layout of the light emitting elements 13 is not particularly limited. In the example of FIG. 2, the plurality of light emitting elements 13 is two-dimensionally arranged in predetermined two directions (the X-axis direction and the Y-axis direction in FIG. 2). FIG. 2 is a plan view for describing an embodiment of the display surface 10A of the display device 10.

The light emitting elements 13 each has a light emitting surface 17 on the first surface side. The light emitting element 13 illustrated in the example of FIG. 1 includes a light emitting portion 24 and a protection portion 15. Furthermore, in the example of FIG. 1, an electrode terminal (not illustrated) connected to the contact plug 23 of the substrate 11 is formed on the second surface side. The light emitting element 13 receives supply of electricity through the electrode terminal to generate light at the light emitting portion 24. The light generated at the light emitting portion 24 is emitted from the light emitting surface 17 in a direction toward the outside of the light emitting element 13 through the uneven portion 18. Note that the light emitting surface 17 is a surface through which light is emitted from the light emitting element 13, and in a case where the uneven portion 18 is integrally formed with the light emitting element 13, the light emitting surface 17 indicates a surface assumed when the uneven portion 18 is removed from a predetermined surface on which convex units 21 forming the uneven portion 18 are formed. Furthermore, in a case where the uneven portion 18 is formed by bonding an uneven film 28 to the light emitting element 13, the light emitting surface 17 indicates a surface exposed when the uneven film 28 that is separate from the light emitting element 13 is removed.

For example, in a case where the light emitting element 13 is an LED, the light emitting portion 24 is formed in a semiconductor multilayer structure. In the semiconductor multilayer structure, for example, a semiconductor layer and an active layer serving as a light emitting layer are layered (not illustrated). The semiconductor layer includes a first compound semiconductor layer and a second compound semiconductor layer. The active layer is interposed, for example, between the first compound semiconductor layer and the second compound semiconductor layer.

The first compound semiconductor layer and the second compound semiconductor layer contain a compound semiconductor, and are doped with an n-type impurity and a p-type impurity, respectively. Examples of the compound semiconductor include a GaN-based compound semiconductor, a GaAsP-based compound semiconductor, an InN-based compound semiconductor and the like. Examples of the n-type impurity include, for example, silicon (Si), selenium (Se), germanium (Ge), tin (Sn), carbon (C), titanium (Ti) or the like. Examples of the p-type impurity include zinc (Zn), magnesium (Mg), beryllium (Be), cadmium (Cd), calcium (Ca), barium (Ba), or oxygen (O).

The active layer contains a compound semiconductor. Examples of the compound semiconductor include materials that can be used as a material of the first compound semiconductor layer and the second compound semiconductor layer as described above. The active layer may include a single compound semiconductor layer, or may include a single quantum well structure (SQW structure) or a multiple quantum well structure (MQW structure). In such a light emitting portion, electricity is supplied to the semiconductor layers through the electrode terminal, and light is generated in the active layer. Note that the light emitting element 13 illustrated in FIG. 1 is an example, and does not limit the structure of the light emitting element applicable to the present disclosure.

The protection portion 15 covers the light emitting portion 24 to restrict exposure of the light emitting portion 24. In the example of FIG. 1, the protection portion 15 covers the upper surface side and the side surface side of the light emitting portion 24. The material forming the protection portion 15 is preferably a material having an insulating property. Furthermore, it is preferable to contain at least one selected from the group consisting of the protection portion 15, a dielectric, a resin, and a metal.

(Uneven Portion)

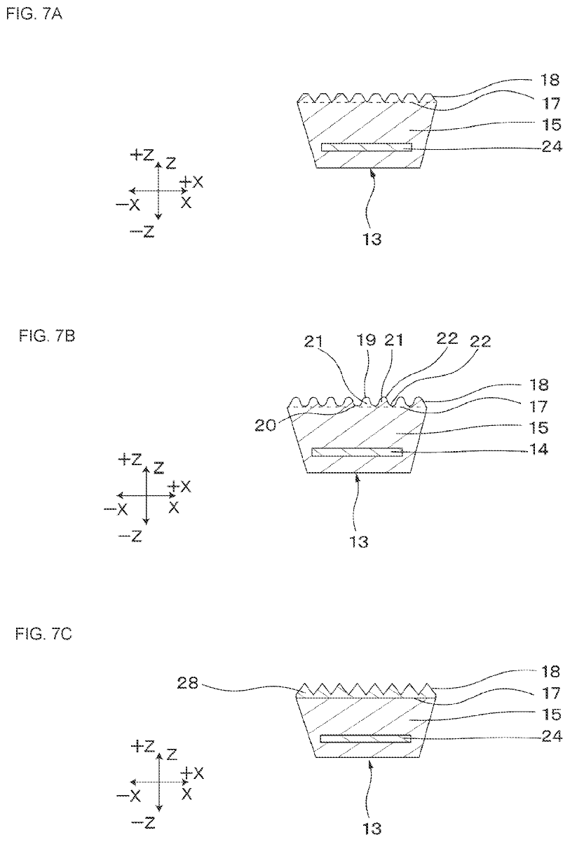

The uneven portion 18 is provided on the light emitting surface of the light emitting element 13. The uneven portion 18 forms a diffraction structure (diffraction grating) that diffracts light emitted from the light emitting surface 17 of the light emitting element 13. In the example of FIG. 1, the uneven portion 18 is integrally formed with the light emitting element 13, on the light emitting surface 17. For example, the uneven portion 18 may be formed using the same material as the material for forming the protection portion 15, on the upper surface side of the protection portion 15 of the light emitting element 13. However, this does not prohibit a case where the uneven portion 18 and the light emitting element 13 are formed separately. For example, the display device 10 in a state where the uneven portion 18 is provided on the light emitting surface 17 of the light emitting element 13 may be formed by bonding the uneven film 28 having an uneven shape corresponding to the uneven portion 18 to the light emitting surface 17 of the light emitting element 13 as illustrated in FIG. 7C.

As illustrated in FIGS. 3A and 3B, the uneven portion 18 includes the plurality of convex units 21 provided at predetermined positions. FIG. 3A is a plan view according to an embodiment of the light emitting element 13. FIG. 3B is a partial enlarged view of a portion of a region S1 in FIG. 1. Each of the convex units 21 forms a convex portion 19, and between adjacent ones of the convex units 21, a concave portion 20 is formed. In the uneven portion 18, a plurality of pairs of the convex portion 19 and the concave portion 20 is periodically formed according to the layout of the plurality of convex units 21.

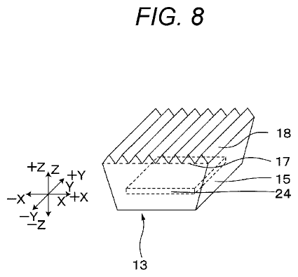

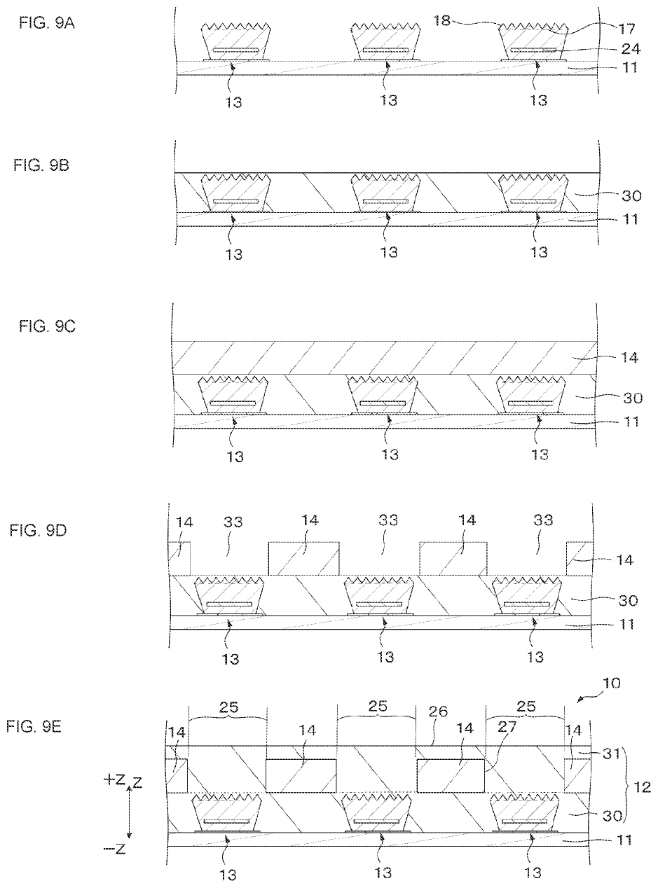

In the example of FIG. 3A, the layout of the plurality of convex units 21 included in the uneven portion 18 is a layout in which the convex units 21 are two-dimensionally arranged in two predetermined directions (the X-axis direction and the Y-axis direction in FIG. 3A). However, this does not limit the layout of the convex units 21. As the layout of the plurality of convex units 21, a layout according to various conditions such as the shape of the convex units 21 may be applied. For example, the convex units 21 may be arranged one-dimensionally as illustrated in FIG. 8.

(Convex Unit)

Examples of the shape of the convex units 21 include, for example, a cone shape as illustrated in FIGS. 1, 3A, and 3B, a frustum shape as illustrated in FIG. 7A, and the like. The planar shape of the convex units 21 is not particularly limited, and may be a triangle, a pentagon, or a polygon having more sides than a pentagon, a circle, or the like in addition to the quadrangle as illustrated in FIG. 3A. In the example of FIG. 3A, the convex units 21 are formed in a quadrangular pyramid shape. Furthermore, as illustrated in FIG. 7B, the convex units 21 may have fillets 22 (chamfered portions). In this case, the uneven portion 18 can form a smooth surface shape. In the example of FIG. 7B, fillets 22 are formed on both the convex portions 19 and the concave portions 20. In a case where the convex units 21 are arranged one-dimensionally, the convex units may have a triangular prism shape as illustrated in FIG. 8, or may have a shape obtained by cutting out a part of a cylinder (semi-cylindrical shape).

(Sealing Layer)

In the display device 10, the sealing layer 12 for sealing the light emitting elements 13 is formed. In the display device illustrated in FIG. 1, an external interface 26 that is the upper surface (first surface) of the sealing layer 12 is a flat surface. Since the upper surface of the sealing layer 12 is a flat surface, it is possible to suppress diffuse reflection of external light on the upper surface of the sealing layer 12. Then, the suppression of diffuse reflection of external light suppresses formation of whitish display surface 10A.

The sealing layer 12 is formed from a resin material or the like having a predetermined refractive index (the value of the refractive index is represented as N1).

The resin material forming the sealing layer 12 is preferably a resin material having an insulating property that allows light generated in the light emitting element 13 to be extracted to the outside. Specifically, examples of the resin material include an ultraviolet curable resin, a thermosetting resin, and the like.

(Low Refractive Index Portion)

In the display device 10 illustrated in the example of FIG. 1, the low refractive index portion 14 is provided inside the sealing layer 12. The low refractive index portion 14 has a refractive index smaller than that of the sealing layer 12. The low refractive index portion 14 is formed in a position of the periphery of immediately above portions 25 above the light emitting elements 13. Note that the immediately above portions 25 are defined as predetermined portions including at least portions, in the sealing layer 12, located immediately above the light emitting elements 13. In the example of FIG. 1, the immediately above portions 25 are defined as cylindrical portions including portions of the sealing layer 12 located immediately above the light emitting elements 13. Furthermore, the periphery of the immediately above portions 25 indicates a periphery along a plane direction (XY plane direction) of the external interface 26 with respect to the immediately above portions 25.

In the example of FIGS. 1 and 2, the low refractive index portion 14 is formed to surround the periphery of the portions of the immediately above portions 25 above the light emitting elements 13. Since the low refractive index portion 14 is formed to surround the immediately above portions 25, it is possible to cause refraction of light at the interface (internal interface 27) between the low refractive index portion 14 and the immediately above portions 25 for light generated from the light emitting elements 13 and traveling in any direction (direction in the XY plane direction), and then to improve light extraction efficiency.

The low refractive index portion 14 is formed from a material having a refractive index (represented as a refractive index N2) smaller than the refractive index N1 of the resin material forming the sealing layer 12. The material forming the low refractive index portion 14 is not particularly limited in its state, and may be an individual resin material similarly to the sealing layer 12, or may be a gas material or a liquid material.

In a case where the low refractive index portion 14 is formed from a resin material, the type of the resin material is preferably a resin material allowing light generated in the light emitting elements 13 to be extracted the outside and having an insulating property, similarly to the sealing layer 12, and can be determined from a resin material similar to the sealing layer 12. In a case where the low refractive index portion 14 is formed from a gas material, examples of the gas material include nitrogen gas, argon gas, hydrogen gas, helium gas, oxygen gas, air, and the like.

The difference between the refractive index N2 of the material forming the low refractive index portion 14 and the refractive index N1 of the resin material forming the sealing layer 12 are not particularly limited, but are preferably 0.1 or more from the viewpoint of improving the light extraction efficiency.

In a case where the low refractive index portion 14 is formed from a solid material such as a resin material, the low refractive index portion 14 is embedded in the sealing layer 12 in the example of FIG. 1, but the present invention is not limited to this example. That is, the upper surface side of the low refractive index portion 14 may be exposed to the upper surface side of the sealing layer 12. However, the low refractive index portion 14 is preferably embedded inside the sealing layer 12 as illustrated in the example of FIG. 1. In a case where the sealing layer 12 covers the upper surface side of the low refractive index portion 14, light traveling in an oblique direction at the interface between the upper surface of the low refractive index portion 14 and the sealing layer 12 can be refracted to a direction closer to the thickness direction (Z-axis direction) of the sealing layer 12 (direction approaching the front direction of the display device 10) at the interface between the upper surface of the low refractive index portion 14 and the sealing layer 12 since the value N2 of the refractive index of the resin material forming the low refractive index portion 14 is smaller than the value N1 of the refractive index of the resin material forming the sealing layer 12. Therefore, the light extraction efficiency in the display device 10 can be improved.

(Thickness of Low Refractive Index Portion)

The thickness (H) of the low refractive index portion 14 preferably satisfies the following Mathematical Formula 1.

H≥(d+a)×tan(90°−min(θc,θd)) Mathematical Formula 1

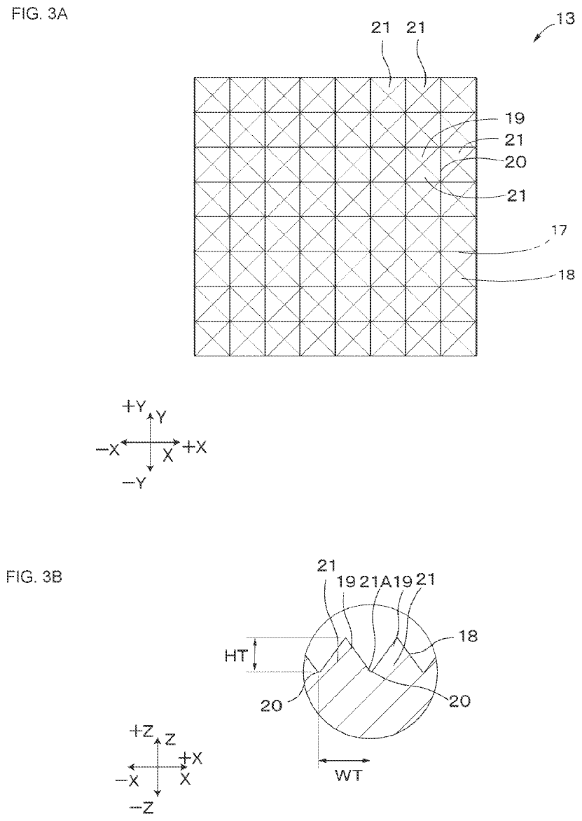

In Mathematical Formula 1 stated above, H represents the thickness of the low refractive index portion 14 as described above, and is the width in the Z-axis direction in FIG. 1. θc represents a critical angle (°) at the contact interface (external interface 26) between the sealing layer 12 and the outside as illustrated in FIG. 4A. The critical angle θc is a value of the minimum incident angle φD that causes total reflection of light at the external interface 26 in FIG. 1, and can be defined as a value of arcsin(N0/N1). Note that N0 is the refractive index of the outer space with the external interface as a boundary, and N1 is the refractive index of the resin material forming the sealing layer 12 as described above. Furthermore, in FIG. 4A, a broken line m is a line indicating a direction parallel to the normal line of the external interface 26, and a solid line LW indicates an example of a ray from the light emitting element 13 toward the external interface 26. FIGS. 4A and 4B are a cross-sectional view and a plan view, respectively, for describing Mathematical Formula 1 stated above. Note that in FIG. 4A, for convenience of description, illustration of the uneven portion 18 is omitted.

As illustrated in FIG. 4A, θd represents an elevation angle (°) formed by the light emitting surface 17 of the light emitting element 13 and the emission direction of light traveling from the light emitting surface 17 toward the outside of the light emitting element 13. As illustrated in FIG. 4B, d represents the longest length of the light emitting surface 17 of the light emitting element 13. a represents a gap length from a position (P1, P2) on the outer peripheral edge of the light emitting surface 17 corresponding to the longest length to the internal interface 27 in plan view of the light emitting element 13.

Since the thickness H of the low refractive index portion 14 is determined to satisfy Mathematical Formula 1 stated above, it is easy to make the incident angle φD less than the critical angle θc for light emitted at any position in the light emitting surface 17. Therefore, the light extraction efficiency in the display device 10 can be improved.

(Interface Shape Between Low Refractive Index Portion and Immediately Above Portion)

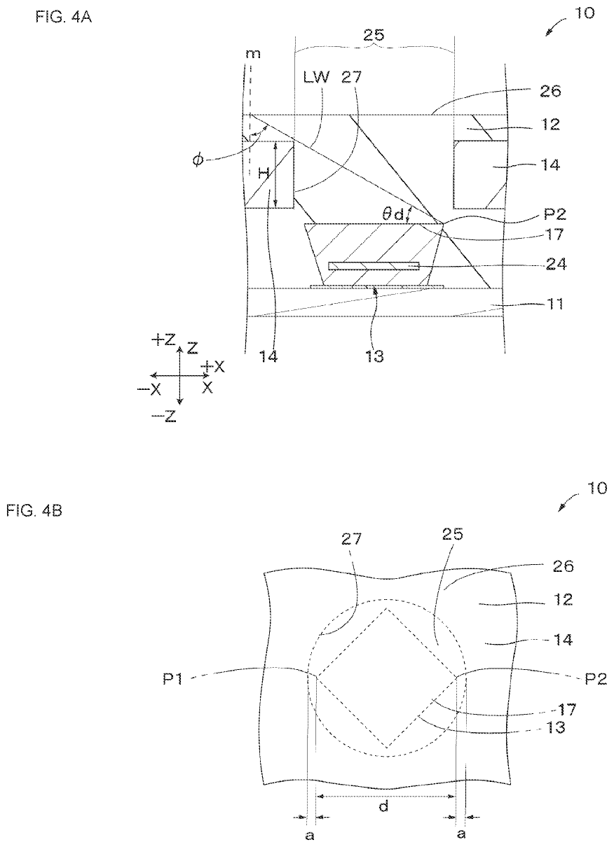

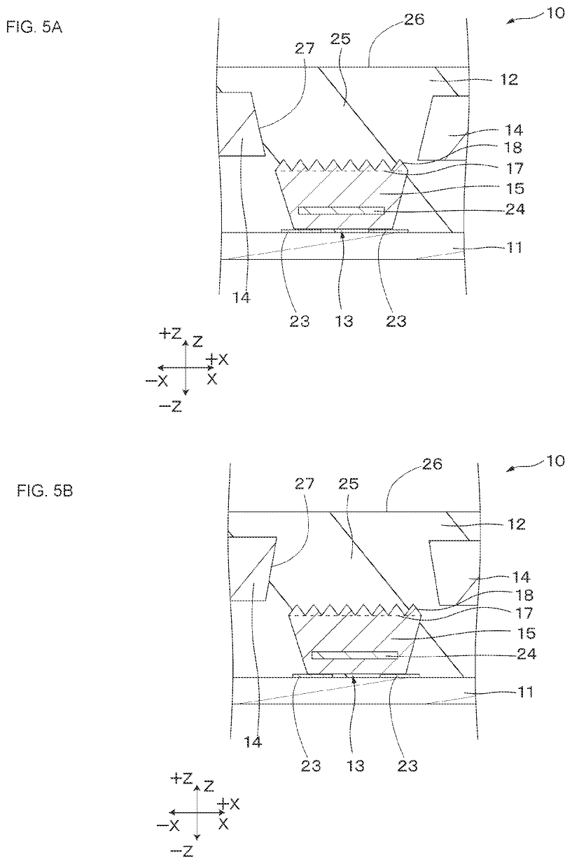

In the example of FIG. 1, the cross-sectional shape of the internal interface 27 between the low refractive index portion 14 and the immediately above portion 25 (cross-sectional shape by a plane orthogonal to the XY plane) is a planar shape with the direction along the thickness direction of the display device 10 (Z-axis direction) as a plane direction, that is, the cross-sectional shape is a non-tapered and planar shape. However, this does not limit the cross-sectional shape of the internal interface 27 to the example of FIG. 1. The cross-sectional shape of the internal interface 27 may be a forward tapered shape as illustrated in FIG. 5A, or may be a reverse tapered shape as illustrated in FIG. 5B.

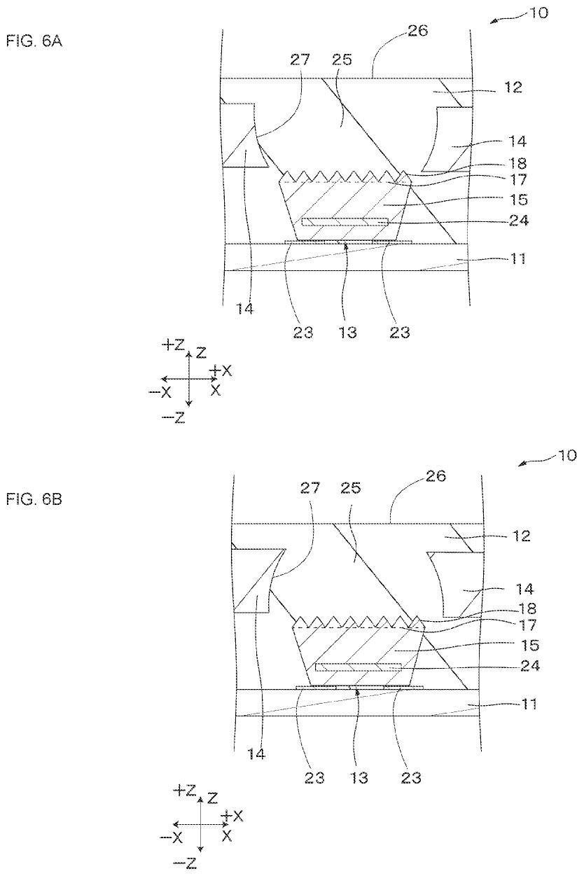

Furthermore, the cross-sectional shape of the internal interface 27 is not limited to a planar shape, and may be a curved surface shape as illustrated in FIGS. 6A and 6B. For example, the cross-sectional shape of the internal interface 27 may be a forward tapered and curved shape (concave surface shape) as illustrated in FIG. 6A, or may be a reverse tapered and curved shape as illustrated in FIG. 6B. Furthermore, the curved shape may be a convex curved surface.

Next, an example of a method of manufacturing the display device 10 according to an embodiment (first embodiment) of the present disclosure will be described.

### 2 Method of Manufacturing Display Device

### [2-1 First Embodiment of Manufacturing Method]

In a first embodiment of the manufacturing method, the plurality of light emitting elements 13 in each of which the uneven portion 18 is provided on the light emitting surface 17 is arranged in a predetermined layout on the first surface of the substrate 11. At this time, a state in which the electrode terminals of the light emitting elements 13 are connected to the contact plugs 23 of the substrate 11 is formed, and a state in which the plurality of light emitting elements 13 is mounted on the first surface of the substrate 11 is formed (FIG. 9A).

Next, a first material for forming the sealing layer 12 is applied onto the first surface of the substrate 11 on which the light emitting elements 13 are mounted at predetermined positions. At this time, a first layer 30 is formed from the first material (FIG. 9B). In the example of FIG. 9B, the light emitting elements 13 are embedded in the first layer 30. As the first material, a resin material such as an ultraviolet curable resin or a thermosetting resin is preferably used as described above.

A second material different from the first material is applied onto the first layer 30. At this time, the low refractive index portion 14 is formed on the first layer 30 from the second material (FIG. 9C). The low refractive index portion 14 is a layer having a refractive index smaller than that of the first layer 30. In the example of FIG. 9C, a resin material having a refractive index smaller than that of the first material is used as the second material.

Furthermore, openings 33 are formed in predetermined portions of the low refractive index portion 14 including at least portions immediately above the light emitting elements 13. The openings 33 can be formed in the low refractive index portion 14 by patterning the low refractive index portion 14 using, for example, a photolithography technique and an etching technique. By forming the openings 33, the first layer 30 is exposed in the openings 33.

The first layer 30 exposed in the openings 33 described above and the low refractive index portion 14 are then covered with the first material. At this time, a second layer 31 is formed from the first material (FIG. 9E). For comparison between the refractive index of the second layer 31 and the refractive index of the low refractive index portion 14, the refractive index of the low refractive index portion 14 is smaller than the refractive index of the second layer 31 similarly to the first layer 30. In the example of FIG. 9E, the first layer 30 and the second layer 31 are continuously integrated at the positions of the openings 33. The sealing layer 12 is then formed by the first layer 30 and the second layer 31. In the sealing layer 12, the portions of the openings 33 and portions formed immediately above the openings 33 serve as the immediately above portions 25. Furthermore, the low refractive index portion 14 is formed between the first layer 30 and the second layer 31, and is embedded in the sealing layer 12. Thus, the display device 10 is formed. Note that, in addition, a surface portion of the second layer 31 may be removed by using, for example, an etching technique or the like to expose the low refractive index portion 14 to the outside. The same applies to a second embodiment of the manufacturing method described later.

The method of manufacturing the display device 10 is not limited to the above-described embodiment, and may be the following method (second embodiment of the manufacturing method).

### [2-1 Second Embodiment of Manufacturing Method]

Similarly to the above-described first embodiment of the manufacturing method, a state in which the plurality of light emitting elements 13 is mounted on the first surface of the substrate 11 is formed (FIG. 9A). Further, the first material for forming the sealing layer 12 is applied onto the first surface of the substrate 11 to form the first layer 30 (FIG. 9B). At this time, in the example of FIG. 9B, the light emitting elements 13 are embedded in the first layer 30 similarly to the above-described first embodiment of the manufacturing method.

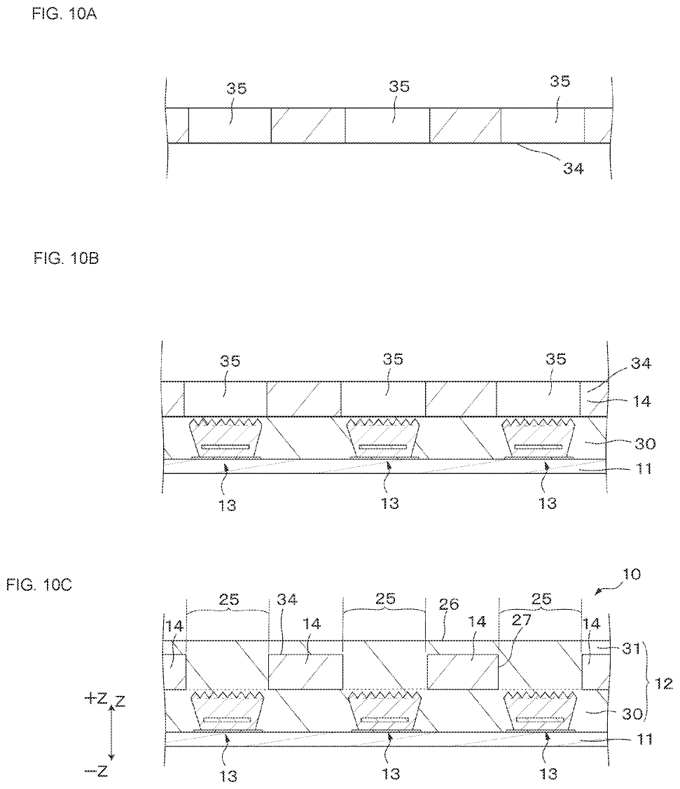

Next, a low refractive index film 34 is prepared in advance. The low refractive index film 34 is a film material having a refractive index smaller than that of the first layer 30. Furthermore, the low refractive index film 34 is a film material for forming openings 35 in portions corresponding to predetermined portions including at least portions immediately above the light emitting elements 13 (FIG. 10A).

The low refractive index film 34 is layered on the first layer 30 (FIG. 10B). At this time, the low refractive index film 34 is arranged such that the spaces in the openings 35 are aligned at positions to be the immediately above portions 25 in plan view of the substrate 11. Furthermore, when aligned, the first layer 30 is exposed from the openings 35. Then, the low refractive index film 34 serves as the low refractive index portion 14.

Further, the first layer 30 exposed from the openings 35 and the low refractive index film 34 are covered with the first material. Thus, the second layer 31 is formed from the first material (FIG. 10C). In the example illustrated in FIG. 10C, the first layer 30 and the second layer 31 are continuously integrated at the positions of openings 33. The sealing layer 12 is then formed by the first layer 30 and the second layer 31. In the sealing layer 12, the portions of the openings 35 and portions formed immediately above the openings 35 serve as the immediately above portions 25. Furthermore, the low refractive index portion 14 formed from the low refractive index film 34 is arranged between the first layer 30 and the second layer 31, and is embedded in the sealing layer 12. Thus, the display device 10 is formed.

### 3 Operation and Effect

The display device 10 is demanded to achieve high contrast and to have an excellent viewing angle characteristic. In order to achieve high contrast in the display device 10, the display device 10 is demanded to achieve high luminance, and thus demanded to improve light extraction efficiency. In addition, since the light emitting elements 13 such as LEDs provided in the display device 10 typically have a light distribution characteristic close to the Lambertian light distribution, it is demanded to suppress total reflection of light, in light generated in the light emitting element 13, at the interface (the external interface 26) between the sealing layer 12 and the outside. According to the display device 10, the low refractive index portion 14 having a refractive index lower than that of the sealing layer 12 is provided at the periphery of the immediately above portions 25 formed immediately above the light emitting elements 13. Therefore, according to the display device 10, as described with a simulation example described later, the amount of light totally reflected at the external interface 26 can be reduced, and the light extraction efficiency can be improved. Therefore, according to the display device 10, the contrast of the display surface 10A can be increased.

Moreover, according to the display device 10, the uneven portions 18 are provided on the light emitting surfaces 17 of the light emitting elements 13. The uneven portions 18 form a diffraction structure. Therefore, according to the display device 10, as will be described with a simulation example described later, according to the display device 10, it is possible to reduce the difference between the brightness when the display surface 10A of the display device 10 is viewed from the front direction and the brightness when viewed from an oblique direction, so that it is possible to suppress the luminance variation for every viewing angle. That is, according to the display device 10, the viewing angle characteristic of light generated by the light emitting elements 13 can be improved.

### 4 Simulation Example

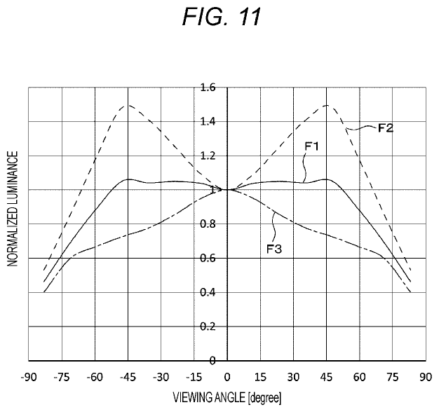

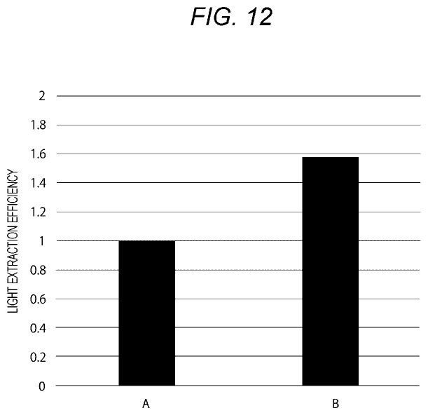

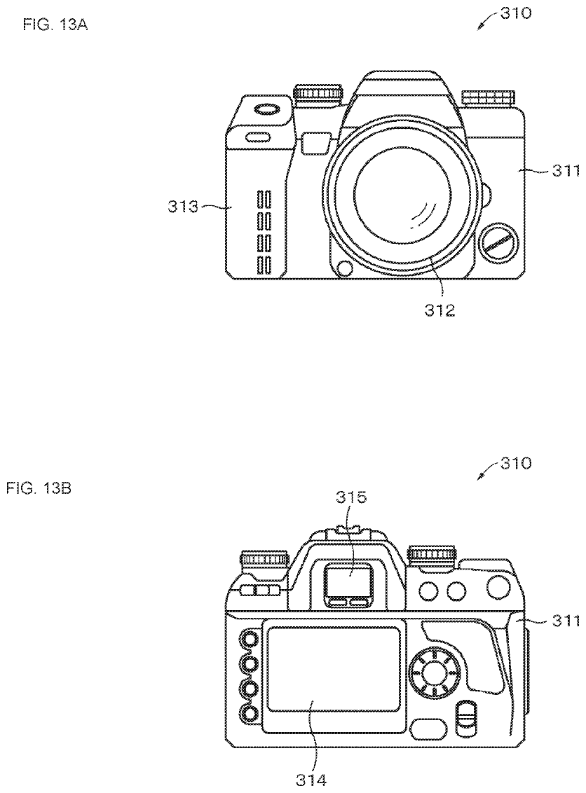

A simulation example of the viewing angle characteristic and the light extraction efficiency regarding light extracted to the outside from the interface (external interface 26) between the sealing layer 12 and the outside in the display device 10 will be described with reference to FIGS. 11 and 12. FIG. 11 is a diagram illustrating results of wave simulation regarding light extracted to the outside in each of the display device 10 according to an embodiment of the present disclosure and comparative display devices 1 and 2. FIG. 12 is a diagram illustrating light extraction efficiency in the display device 10 according to one of the disclosed embodiments and a comparative display device 3.

The display device 10 illustrated in FIGS. 1 to 3A and 3B was assumed as the display device according to one of the embodiments of the present disclosure. The following condition (condition A) was set as a condition defining the structure of the display device 10.

(Condition of Simulation)

(Condition A)

The light emitting elements 13 are formed in a quadrangular shape in plan view,

the uneven portions 18 each include a combination of the convex portion 19 and the concave portion 20 periodically formed by the plurality of convex units 21,

the convex units 21 are integrally formed on the light emitting surface 17 of the light emitting element 13 and each are formed in a quadrangular pyramid shape having a square shape in plan view,

the width (length of one side) of base ends 21A of the convex units 21 is 2.5 μm (reference sign WT in FIG. 3B) and the height is 2.5 μm (reference sign HT in FIG. 3B), and

the thickness of the low refractive index portion 14 is 20 μm (reference sign H in FIG. 1),

the refractive index N1 of the resin material forming the low refractive index portion 14 is 1.3,

the refractive index N2 of the resin material forming the sealing layer 12 is 1.5, and

the immediately above portions 25 are formed in a cylindrical shape and have a diameter of 30 μm (reference sign W in FIG. 1).

As a comparative display device (comparative display device 1), one in which the uneven portion 18 is omitted from the display device 10 illustrated in FIG. 1 was assumed. A condition defining the structure of the comparative display device 1 was set to be the same as that of the condition A described above except that the condition of the uneven portion 18 was omitted.

Moreover, as a comparative display device (comparative display device 2), one in which the low refractive index portion 14 is omitted from the display device 10 illustrated in FIG. 1 was assumed. A condition defining the structure of the comparative display device 2 was set to be the same as that of the condition A described above except that the condition of the low refractive index portion 14 was omitted.

Moreover, as the comparative display device (comparative display device 3), a display device in which the uneven portion 18 and the low refractive index portion 14 are omitted from the display device 10 illustrated in FIG. 1 (conventional display device) was assumed. A condition defining the structure of the comparative display device 2 was set to be the same as that of the condition A described above except that the condition of the uneven portion 18 and the low refractive index portion 14 was omitted.

(Simulation Performing Method)

(Wave Simulation)

The simulation regarding the viewing angle characteristic of light extracted to the outside from the light emitting surface 17 of the light emitting element 13 was performed by wave simulation. At this time, a case where the wavelength of light generated from the light emitting element 13 is 0.46 μm was assumed. Under this assumption, the wave simulation was performed as follows. First, the state of light emitted from the uneven portion 18 of the light emitting element 13 was calculated by diffraction calculation (wave calculation). Next, the result of the diffraction calculation was converted into surface characteristic. After the conversion into the surface characteristic, viewing angle characteristic calculation (ray tracking calculation) was performed for the light from the light emitting element 13 toward the external interface 26. By the ray tracking calculation, the simulation results of the viewing angle characteristic in a case where the wavelength of light generated from the light emitting element 13 is 0.46 μm were obtained. Here, an example in which simulation is performed regarding the viewing angle characteristic of blue light having a wavelength of 0.46 μm has been described, but the color and wavelength of light emitted from the light emitting element 13 are not particularly limited. For example, the color of the light emitted from the light emitting element 13 may be red light, green light, or the like.

The results of the wave simulation are as illustrated in the graph of FIG. 11. In the graph of FIG. 11, the horizontal axis represents the viewing angle (° (degree)), and the vertical axis represents the normalized luminance. The normalized luminance corresponds to luminance at each viewing angle when luminance in a direction in which the viewing angle is 0 (degree) is 1. In FIG. 11, the wave simulation result for the display device according to one of the embodiments of the present disclosure is indicated by a solid line F1. The wave simulation result for the comparative display device 1 is indicated by a broken line F2. The wave simulation result for the comparative display device 2 is indicated by an alternate long and short dash line F3.

(Simulation Regarding Light Extraction Efficiency)

Furthermore, simulation was performed regarding the light extraction efficiency in the display device 10 according to one of the embodiments of the present disclosure. The simulation regarding the light extraction efficiency was performed by calculating the light extraction efficiency on the basis of the amount of light extracted from the external interface 26 with assumption of a case where the wavelength of light generated from the light emitting element 13 is 0.46 μm (blue light). The light amount in this case can be specified on the basis of the results of the wave simulation. The simulation regarding the light extraction efficiency was also performed for the comparative display device 3 similarly to the case of the display device 10 according to one of the embodiments of the present disclosure.

The simulation results regarding the light extraction efficiency are as illustrated in the graph of FIG. 12. Note that, in FIG. 12, a bar graph A is a graph for the comparative display device 3, and a bar graph B is a graph for the display device 10 according to one of the embodiments of the present disclosure. Furthermore, in FIG. 12, the light extraction efficiency of the light extracted from the external interface 26 is set to 1. The light extraction efficiency of the light extracted from the external interface 26 for the display device according to one of the embodiments of the present disclosure is indicated by a relative ratio with respect to the light intensity of the comparative display device 3.

From the simulation results illustrated in FIG. 12, it was confirmed that the light extraction efficiency of the display device 10 according to one of the embodiments of the present disclosure exceeds 1 as a relative ratio with respect to the comparative display device 3. Therefore, it was confirmed that the display device 10 was superior in light extraction efficiency to the comparative display device 3. In addition, since the comparative display device 3 corresponds to a conventional display device, it has been confirmed that the light extraction efficiency of the display device 10 according to one of the embodiments of the present disclosure is improved as compared with the conventional display device.

Furthermore, from the results of the wave simulation illustrated in FIG. 11, in the case where only the low refractive index portion 14 is provided as in the comparative display device 1, the maximum value (peak) of the normalized luminance is reached when the viewing angle is set to a predetermined value larger than 0 (degree) in the viewing angle characteristic (broken line F2 in FIG. 11). On the other hand, in a case where the uneven portion 18 is provided as in the comparative display device 2, the peak of the normalized luminance is reached at the viewing angle 0 (degree) in the viewing angle characteristic (alternate long and short dash line F3 in FIG. 11). Furthermore, when the display device 10 includes the low refractive index portion 14 and the uneven portion 18, the normalized luminance is stabilized within a predetermined viewing angle range as compared with the case where only the low refractive index portion 14 is provided as in the comparative display device 1. As described above, it has been confirmed that since the display device 10 includes the low refractive index portion 14 and the uneven portion 18, luminance is stabilized within a predetermined viewing angle range including the front direction (viewing angle 0 (degree)) of the display surface 10A, and excellent viewing angle characteristic is achieved.

### 5 Application Examples

(Electronic Device)

The display device 10 according to the above-described embodiment may be provided in various electronic devices. In particular, it is preferably provided in a device demanded to have a high resolution for enlarged display and for use near the eyes such as an electronic view finder of a video camera or a single-lens reflex camera, a head-mounted display, or the like.

### Specific Example 1

FIG. 13A is a front view illustrating an example of an external appearance of a digital still camera 310. FIG. 13B is a back view illustrating an example of an external appearance of the digital still camera 310. This digital still camera 310 is of a lens-interchangeable single-lens reflex type and includes, for example, an interchangeable imaging lens unit (interchangeable lens) 312 substantially at the center on the front side of a camera main body portion (camera body) 311, and a grip portion 313 to be held by a photographer on the front left side.

A monitor 314 is provided at a position shifted to the left from the center of the back surface of the camera main body portion 311. An electronic view finder (eyepiece window) 315 is provided above the monitor 314. By looking in the electronic view finder 315, a photographer can determine the composition while visually recognizing an optical image of a subject guided from the imaging lens unit 312. As the electronic view finder 315, any of the display devices 10 according to the above-described embodiment can be used.

### Specific Example 2

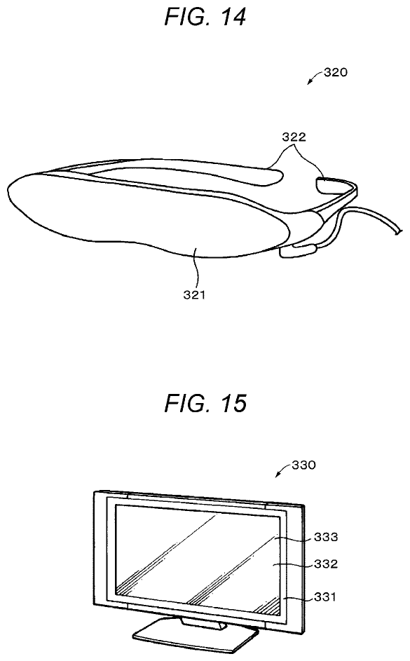

FIG. 14 is a perspective view illustrating an example of an external appearance of a head mounted display 320. The head mounted display 320 includes, for example, ear hooking portions 322 to be worn on the head of a user on both sides of an eye glasses shaped display unit 321. As the display unit 321, any of the display devices 10 according to the above-described embodiment can be used.

### Specific Example 3

FIG. 15 is a perspective view illustrating an example of an external appearance of a television device 330. The television device 330 includes, for example, a video display screen unit 331 including a front panel 332 and a filter glass 333, and the video display screen unit 331 is configured by any of the display devices 10 according to the above-described embodiment.

### 6 Illumination Device

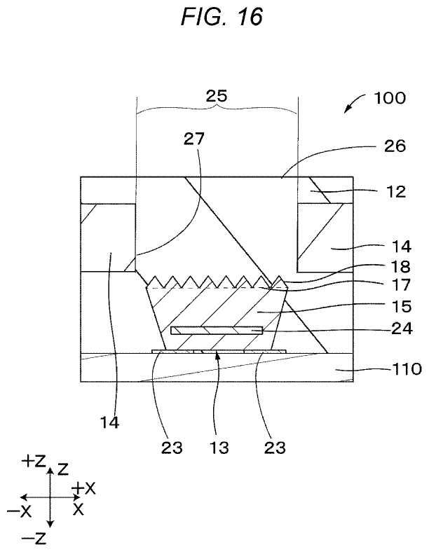

The configuration of the display device 10 of the present disclosure can also be applied to an illumination device as illustrated in FIG. 16. FIG. 16 is a cross-sectional view illustrating a configuration example of an illumination device 100 according to an embodiment of the present disclosure. The illumination device 100 includes a substrate 110, a light emitting element 13, an uneven portion 18, a sealing layer 12, and a low refractive index portion 14. In the illumination device 100 illustrated in the example of FIG. 16, a case where the number of light emitting element 13 is one has been described as an example, but a plurality of the light emitting elements 13 may be provided similarly to those illustrated in the display device 10.

In the illumination device 100, as long as various circuits for exerting an illumination function such as a power supply circuit for supplying power to the light emitting element 13 are provided, various circuits for driving the light emitting element 13 provided on the substrate 11 of the display device 10 may be omitted. As the material of the substrate 110, a material similar to that of the substrate 11 described above may be used.

In the illumination device 100, a configuration other than the various circuits described above may be the same as the configuration of the display device 10 described above. Therefore, the light emitting element 13, the uneven portion 18, the sealing layer 12, and the low refractive index portion 14 in the illumination device 100 are configured in the same manner as the display device 10.

(Operation and Effect)

According to the illumination device 100, it is possible to obtain a device excellent in light extraction efficiency and a device having high luminance.

Although the display device, the method of manufacturing the display device, the application examples, and the illumination device according to the present disclosure have been specifically described above, the present disclosure is not limited to the display device, the method of manufacturing the display device, the application examples, and the illumination device described above, and various modifications based on the technical idea of the present disclosure are possible.

For example, the configurations, methods, steps, shapes, materials, numerical values, and the like stated in the display device, the manufacturing method of the display device, the application examples, and the illumination device described above are merely examples, and different configurations, methods, steps, shapes, materials, numerical values, and the like may be used as necessary.

The configurations, methods, steps, shapes, materials, numerical values, and the like stated in the display device, the manufacturing method of the display device, the application examples, and the illumination device described above can be combined with each other without departing from the gist of the present disclosure.

The materials exemplified in the display device, the method of manufacturing the display device, the application examples, and the illumination device described above can be used alone or in combination of two or more unless otherwise specified.

Furthermore, the present disclosure may also have the following configurations.
(1) A display device including:
a substrate;
a light emitting element attached to the substrate; and
a sealing layer that seals the light emitting element,
in which an uneven portion having a plurality of concave portions and a plurality of convex portions is provided on the light emitting surface of the light emitting element, and
a low refractive index portion having a refractive index lower than that of the sealing layer is formed at a periphery of an immediately above portion above the light emitting element in the sealing layer.
(2) The display device according to above-described (1),
in which the low refractive index portion surrounds a periphery of the immediately above portion.
(3) The display device according to above-described (1) or (2),
in which the low refractive index portion is embedded in the sealing layer.
(4) The display device according to any one of above-described (1) to (3),
in which an upper surface of the sealing layer is a flat surface. (5) The display device according to any one of above-described (1) to (4),
in which

H≥(d+a)×tan(90°−min(θc,θd)) Mathematical Formula 1

is satisfied where H represents a thickness of the low refractive index portion, θc represents a critical angle (°) at a contact interface between the sealing layer and the outside, θd represents an elevation angle (°) formed by the light emitting surface of the light emitting element and an emission direction of light emitted from the light emitting surface of the light emitting element, d represents a longest length of the light emitting surface of the light emitting element, and a represents a gap length from a position on an outer peripheral edge of the light emitting surface corresponding to the longest length to the contact interface in a plan view of the light emitting element.
(6) The display device according to any one of above-described (1) to (5),
in which a cross-sectional shape of an interface between the low refractive index portion and the immediately above portion is any of a forward tapered shape, a non-tapered shape, and a reverse tapered shape.
(7) The display device according to any one of above-described (1) to (6),
in which an interface between the low refractive index portion and the immediately above portion is a curved surface shape or a planar shape.
(8) The display device according to any one of above-described (1) to (7),
in which the plurality of convex portions is formed from a plurality of convex units arranged two-dimensionally, and
the convex units have a cone shape or a frustum shape.
(9) The display device according to any one of above-described (1) to (8),
in which the uneven portion periodically forms a combination of the concave portion and the convex portion.
(10) The display device according to any one of above-described (1) to (9),
in which the uneven portion forms a diffraction structure.
(11) The display device according to any one of above-described (1) to (10),
in which the uneven portion is integrally formed on the light emitting surface of the light emitting element.
(12) The display device according to any one of above-described (1) to (11),
in which an uneven film having the uneven portion is provided on the light emitting surface of the light emitting element.
(13) An electronic device including the display device according to any one of above-described (1) to (12).
(14) A method of manufacturing a display device, including:
forming a first layer in which a light emitting element is embedded by applying a first material to form a sealing layer that seals the light emitting element onto a substrate on which the light emitting element provided with an uneven portion on a light emitting surface is mounted at a predetermined position;
forming a low refractive index portion having a refractive index smaller than that of the first layer by applying a second material different from the first material onto the first layer;
exposing the first layer from an opening by forming the opening in a predetermined portion of the low refractive index portion, the predetermined portion including at least a portion immediately above the light emitting element; and
forming a second layer by applying the first material to cover the first layer exposed in the opening and the low refractive index portion, the second layer and the first layer serving as the sealing layer.
(15) A method of manufacturing a display device, including:
forming a first layer in which a light emitting element is embedded by applying a first material to form a sealing layer that seals the light emitting element onto a substrate on which the light emitting element provided with an uneven portion on a light emitting surface is mounted at a predetermined position;
layering a low refractive index film on the first layer, the low refractive index film having a refractive index smaller than that of the first layer, the low refractive index film having an opening formed in a portion corresponding to a predetermined portion including at least a portion immediately above the light emitting element; and
forming a second layer by applying the first material to cover the first layer exposed in the opening and the low refractive index film, the first layer and the second layer serving as the sealing layer.

### REFERENCE SIGNS LIST

10 Display device
11 Substrate
12 Sealing layer
13 Light emitting element
14 Low refractive index portion
15 Protection portion
17 Light emitting surface
18 Uneven portion
19 Convex portion
20 Concave portion
21 Convex unit
22 Fillet
24 Light emitting portion
25 Immediately above portion
26 External interface
27 Interface
28 Uneven film
100 Illumination device
310 Digital still camera (electronic device)
320 Head mounted display (electronic device)
330 Television device (electronic device)

1. A display device comprising:
a substrate;
a light emitting element having a light emitting surface and attached to the substrate; and
a sealing layer that seals the light emitting element,
wherein an uneven portion having a plurality of concave portions and a plurality of convex portions is provided on the light emitting surface of the light emitting element, and
a low refractive index portion having a refractive index lower than that of the sealing layer is formed at a periphery of an immediately above portion above the light emitting element in the sealing layer.

2. The display device according to claim 1,
wherein the low refractive index portion surrounds a periphery of the immediately above portion.

3. The display device according to claim 1,
wherein the low refractive index portion is embedded in the sealing layer.

4. The display device according to claim 1,
wherein an upper surface of the sealing layer is a flat surface.

5. The display device according to claim 1,
wherein
H≥(d+a)×tan(90°−min(θc,θd)) Mathematical Formula 1
is satisfied where H represents a thickness of the low refractive index portion, θc represents a critical angle (°) at a contact interface between the sealing layer and the outside, θd represents an elevation angle (°) formed by the light emitting surface of the light emitting element and an emission direction of light emitted from the light emitting surface of the light emitting element, d represents a longest length of the light emitting surface of the light emitting element, and a represents a gap length from a position on an outer peripheral edge of the light emitting surface corresponding to the longest length to the contact interface in a plan view of the light emitting element.

6. The display device according to claim 1,
wherein a cross-sectional shape of an interface between the low refractive index portion and the immediately above portion is any of a forward tapered shape, a non-tapered shape, and a reverse tapered shape.

7. The display device according to claim 1,
wherein an interface between the low refractive index portion and the immediately above portion is a curved surface shape or a planar shape.

8. The display device according to claim 1,
wherein the plurality of convex portions is formed from a plurality of convex units arranged two-dimensionally, and
the convex units have a cone shape or a frustum shape.

9. The display device according to claim 1,
wherein the uneven portion periodically forms a combination of the concave portion and the convex portion.

10. The display device according to claim 1,
wherein the uneven portion forms a diffraction structure.

11. The display device according to claim 1,
wherein the uneven portion is integrally formed on the light emitting surface of the light emitting element.

12. The display device according to claim 1,
wherein an uneven film having the uneven portion is provided on the light emitting surface of the light emitting element.

13. An electronic device comprising the display device according to claim 1.

14. A method of manufacturing a display device, comprising:
forming a first layer in which a light emitting element is embedded by applying a first material to form a sealing layer that seals the light emitting element onto a substrate on which the light emitting element provided with an uneven portion on a light emitting surface is mounted at a predetermined position;
forming a low refractive index portion having a refractive index smaller than that of the first layer by applying a second material different from the first material onto the first layer;
exposing the first layer from an opening by forming the opening in a predetermined portion of the low refractive index portion, the predetermined portion including at least a portion immediately above the light emitting element; and
forming a second layer by applying the first material to cover the first layer exposed in the opening and the low refractive index portion, the second layer and the first layer serving as the sealing layer.

15. A method of manufacturing a display device, comprising:
forming a first layer in which a light emitting element is embedded by applying a first material to form a sealing layer that seals the light emitting element onto a substrate on which the light emitting element provided with an uneven portion on a light emitting surface is mounted at a predetermined position;
layering a low refractive index film on the first layer, the low refractive index film having a refractive index smaller than that of the first layer, the low refractive index film having an opening formed in a portion corresponding to a predetermined portion including at least a portion immediately above the light emitting element; and
forming a second layer by applying the first material to cover the first layer exposed in the opening and the low refractive index film, the first layer and the second layer serving as the sealing layer.
